(19) United States
(12) Patent Application Publication
(10) Pub. No.: US 2026/0214982 A1
(43) Pub. Date: Jul. 23, 2026

(54) DIFFERENTIAL PAIR STRUCTURE

(71) Applicant: ASMedia Technology Inc., New Taipei City (TW)

(72) Inventor: Chieh-Jui Ho, New Taipei City (TW)

(73) Assignee: ASMedia Technology Inc., New Taipei City (TW)

(21) Appl. No.: 19/055,468

(22) Filed: Feb. 17, 2025

(30) Foreign Application Priority Data
Jan. 20, 2025 (TW) 114102258

(51) Int. Cl. H10D 84/85

(52) U.S. Cl. CPC H10D 84/859

(57) ABSTRACT

A differential pair structure includes a first well, a first electrode, a second electrode, a first transistor pair and a second transistor pair. The first electrode and the second electrode are arranged in the first well. The first transistor has a plurality of sub-transistors arranged in the first well symmetrically with respect to the first electrode along a first direction. The second transistor has a plurality of sub-transistors arranged in the first well symmetrically with respect to the second electrode along the first direction. The first electrode and the second electrode respectively receive a first bias and a second bias.

### CROSS-REFERENCE TO RELATED APPLICATION

This application claims the priority benefit of Taiwan application serial no. 114102258, filed on Jan. 20, 2025. The entirety of the above-mentioned patent application is hereby incorporated by reference herein and made a part of this specification.

### BACKGROUND

### Technical Field

The disclosure relates to a differential pair structure, and in particular relates to a differential pair structure that may reduce layout area.

### Description of Related Art

Differential pairs are indispensable elements in various communication equipment. Therefore, how to match transistors so that the threshold voltage and other properties of two transistors are the same is an important topic in the field of communications. In the prior art, two transistors are arranged in two different wells, and the mismatch between the two transistors is eliminated by applying voltages to the two transistors through electrodes arranged in the same well as the transistors. However, such an arrangement results in a larger distance between the transistors, increases the area required for circuit layout, and increases the parasitic effects generated by the connections between the transistors.

### SUMMARY

A differential pair structure that may save space and reduce parasitic effects is provided in the disclosure.

The differential pair structure of the disclosure includes a first well, a first electrode, a second electrode, a first transistor pair, and a second transistor pair. The first electrode and the second electrode are arranged in the first well. The first transistor pair is arranged in the first well symmetrically with respect to the first electrode along a first direction. The second transistor pair is arranged in the first well symmetrically with respect to the second electrode along a first direction. The first electrode and the second electrode respectively receive a first bias and a second bias.

Based on the above, the disclosure forms a structure that may eliminate the mismatch between transistors by arranging the transistor pair and the electrode in the same well, and using the electrode as the symmetry point of the transistor pair. Through the above approach, the layout spacing between the transistor pair may be effectively reduced, which may reduce the parasitic effects caused by the connections therebetween, effectively save space costs and reduce signal interference caused by parasitic effects.

### BRIEF DESCRIPTION OF THE DRAWINGS

FIG. 1 is a top view schematic diagram of a differential pair structure of an embodiment of the disclosure.

FIG. 2A is a schematic diagram of the lateral structure of a differential pair structure of an embodiment of the disclosure.

FIG. 2B is a top view schematic diagram of a differential pair structure of an embodiment of the disclosure.

FIG. 3 is a top view schematic diagram of a differential pair structure of an embodiment of the disclosure.

FIG. 4 is a top view schematic diagram of a differential pair structure of an embodiment of the disclosure.

FIG. 5 is a schematic diagram of an equivalent circuit of differential pair structures of an embodiment of the disclosure.

FIG. 6 is a schematic diagram of the lateral structure of a differential pair structure of an embodiment of the disclosure.

FIG. 7 is a top view schematic diagram of a differential pair structure of an embodiment of the disclosure.

FIG. 8 is a schematic diagram of an equivalent circuit of differential pair structures of an embodiment of the disclosure.

### DETAILED DESCRIPTION OF DISCLOSED EMBODIMENTS

A portion of the embodiments of the disclosure will be described in detail with reference to the accompanying drawings. Element symbol referenced in the following description will be regarded as the same or similar element when the same element symbol appears in different drawings. These examples are only a portion of the disclosure and do not disclose all possible embodiments of the disclosure. More precisely, these embodiments are only examples within the scope of the patent application of the disclosure.

The terms “upper”, “lower”, “vertical”, “horizontal” and other directions used in this article are based on the directions shown in the drawings. Unless the applicant specifically emphasizes and limits their functions, they are only for the convenience of description. This disclosure does not indicate or imply that the device or component referred to must have a specific orientation, or be constructed and operated in a specific orientation, and therefore is not to be construed as a limitation of the disclosure.

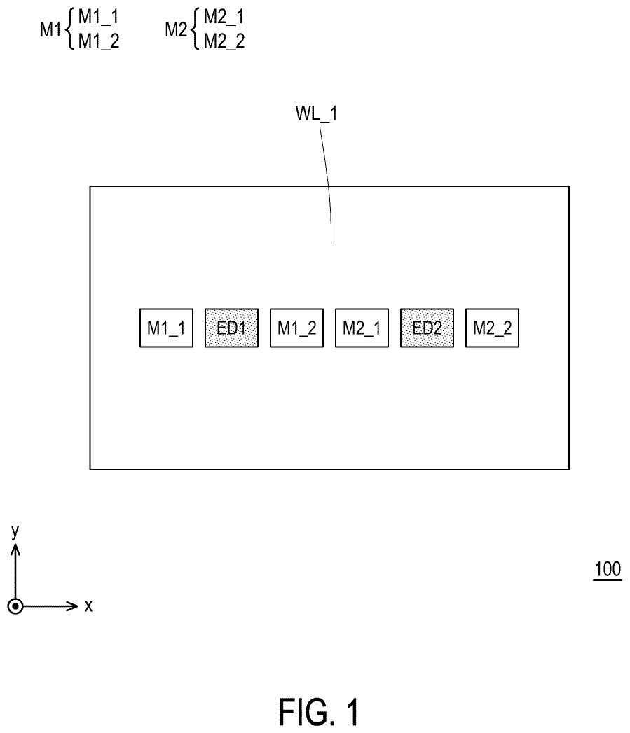

Referring to FIG. 1, FIG. 1 is a top view schematic diagram of a differential pair structure 200 of an embodiment of the disclosure. As shown in FIG. 1, the differential pair structure 100 includes a well WL_1, an electrode ED1, an electrode ED2, a transistor M1, and a transistor M2. The transistor M1 includes a sub-transistor M1_1 and a sub-transistor M1_2, and the transistor M2 includes a sub-transistor M2_1 and a sub-transistor M2_2. In detail, the electrode ED1 and the electrode ED2 are arranged in the well WL_1. The transistor M1 is arranged in the well WL_1 symmetrically with respect to the electrode ED1 along the direction x. Similarly, the transistor M2 is arranged in the well WL_1 symmetrically with respect to the electrode ED2 along the direction x. Here, the sub-transistors M1_1 and M1_2 may be transistors with the same electrical characteristics, and the sub-transistors M2_1 and M2_2 may be transistors with the same electrical characteristics. The so-called “symmetry” means that the distances of the sub-transistors M1_1 and M1_2 relative to the electrode ED1 are the same, and the distances of the sub-transistors M2_1 and M2_2 relative to the electrode ED2 are the same. Additionally, in this embodiment, the electrodes ED1 to ED2 may be voltage pick-up contacts.

In addition, the electrode ED1 and the electrode ED2 are respectively configured to receive the bias VB1 and the bias VB2. In this way, the deviation between the sub-transistors M1_2 and M2_1 may be eliminated by adjusting the biases VB1 and VB2 to increase the matching degree of the sub-transistors M1_2 and M2_1. In other words, the threshold voltage difference between the sub-transistor M1_2 and the sub-transistor M2_1 may be eliminated through the body effect, so that the transistor M1 and the transistor M2 may be combined as a differential pair. It is worth mentioning that the matched sub-transistor M1_2 and the sub-transistor M2_1 may have a smaller spacing since they are located in the same well. Therefore, the differential pair structure 100 may save space cost and reduce parasitic effects on the wiring. Additionally, in this embodiment, the bias VB1 may be different from the bias VB2.

Continue referring to FIG. 1, in more detail, both the sub-transistor M1_1 and the sub-transistor M1_2 may be arranged in the well WL_1. The sub-transistor M1_1 may be adjacent to one side of the electrode ED1, and the sub-transistor M1_2 may be adjacent to the other side of the electrode ED1. Similarly, both the sub-transistor M2_1 and the sub-transistor M2_2 may be arranged in the well WL_1. The sub-transistor M2_1 may be adjacent to one side of the electrode ED2, and the sub-transistor M2_2 may be adjacent to the other side of the electrode ED2.

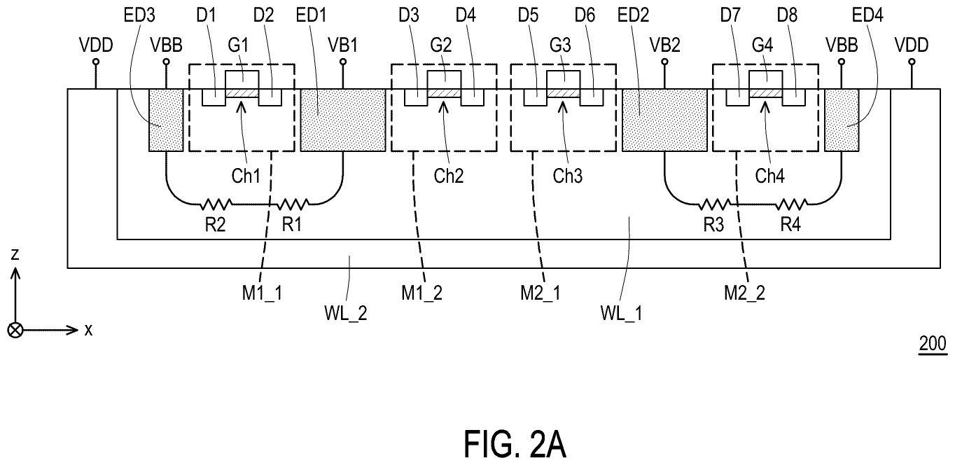

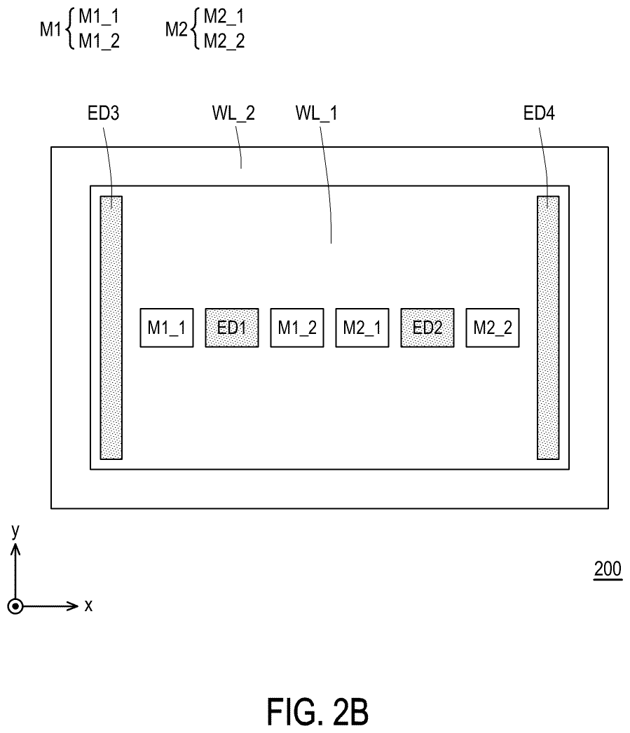

Referring to FIG. 2A, FIG. 2A is a schematic diagram of the lateral structure of a differential pair structure 200 of an embodiment of the disclosure. In this embodiment, the sub-transistor M1_1 may include a heavily doped region D1, a heavily doped region D2, and a gate structure G1. The heavily doped region D1 and the heavily doped region D2 are arranged in the well WL_1 along the direction x. The gate structure G1 covers the channel region Ch1 and is configured to receive a bias to form the channel region Ch1 between the heavily doped region D1 and the heavily doped region D2. Similarly, the sub-transistor M1_2 may include a heavily doped region D3, a heavily doped region D4, and a gate structure G2. The sub-transistor M2_1 may include a heavily doped region D5, a heavily doped region D6, and a gate structure G3. The sub-transistor M2_2 may include a heavily doped region D7, a heavily doped region D8, and a gate structure G4. A channel region Ch2 may be formed between the heavily doped region D3 and the heavily doped region D4. A channel region Ch3 may be formed between the heavily doped region D5 and the heavily doped region D6. A channel region Ch4 may be formed between the heavily doped region D7 and the heavily doped region D8. The other arrangements of the two heavily doped regions and the gate structure of the sub-transistors M1_2, M2_1, and M2_2 are the same as those of the sub-transistor M1_1, and are not repeated herein.

In addition, in this embodiment, the heavily doped regions D1 to D8 may all be N-type heavily doped regions. Correspondingly, the well WL_1 may be a P-type well. In this way, the sub-transistors M1_1, M1_2, M2_1, and M2_2 may be N-type transistors.

In addition, compared with the differential pair structure 100 of FIG. 1, the differential pair structure 200 may further include the well WL_2. The well WL_1 is arranged in the well WL_2. The conductive polarity of the well WL_2 is opposite to the conductive polarity of the well WL_1. In other words, when the sub-transistors M1_1, M1_2, M2_1, and M2_2 are N-type transistors, the well WL_2 may be a deep N-well. The well WL_2 may be configured to receive the power supply voltage VDD.

Referring to FIG. 2A and FIG. 2B together, FIG. 2B is a top view schematic diagram of a differential pair structure 200 of an embodiment of the disclosure. In this embodiment, the differential pair structure 200 may further include an electrode ED3 and an electrode ED4. As shown in FIG. 2B, the electrode ED3 and the electrode ED4 are respectively arranged on two sides of the well WL_1 parallel to the direction y. As shown in FIG. 2A, the electrode ED3 and the electrode ED4 may be configured to receive the same bias VBB. The bias VBB may be equal to the average value of the bias VB1 and the bias VB2, that is, (VB1+VB2)/2.

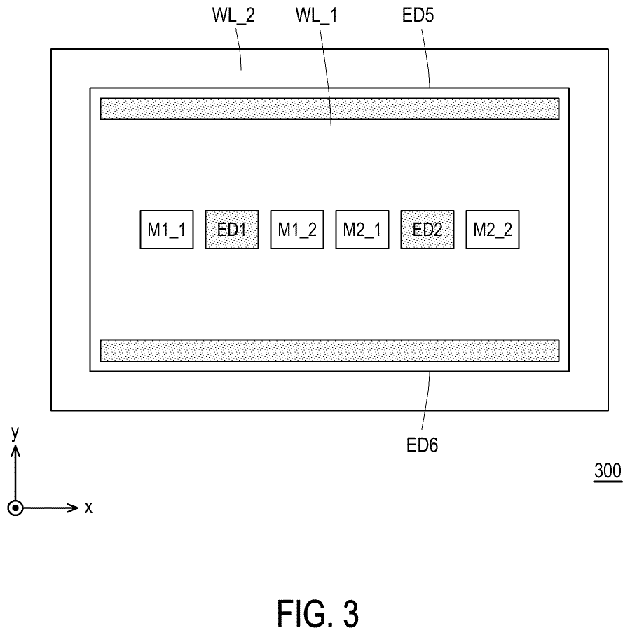

Referring to FIG. 2B and FIG. 3 together, FIG. 3 is a top view schematic diagram of a differential pair structure 300 of an embodiment of the disclosure. Different from the differential pair structure 200 in FIG. 2B, the differential pair structure 300 includes an electrode ED5 and an electrode ED6 instead of the electrode ED3 and the electrode ED4. However, similar to the electrodes ED3 and ED4 of the differential pair structure 200, the electrodes ED5 and ED6 may also be configured to receive the bias VBB.

Additionally, in some embodiments, the differential pair structure may simultaneously include electrodes ED3 and ED4 as well as electrodes ED5 and ED6.

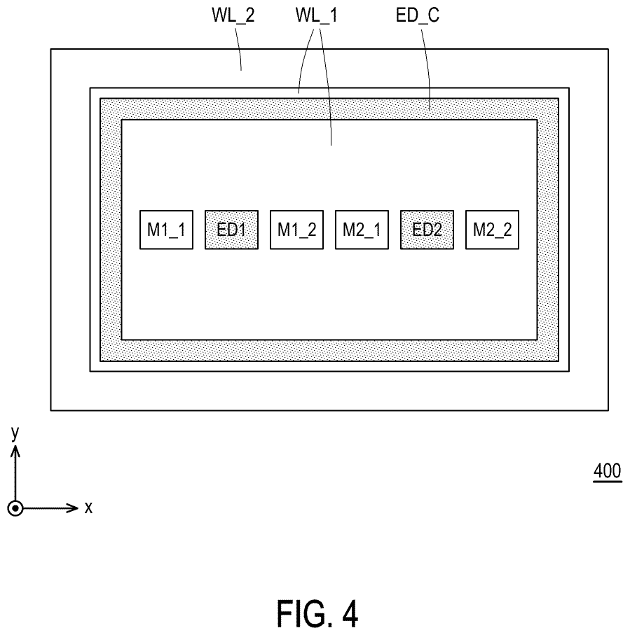

Referring to FIG. 2B and FIG. 4 together, FIG. 4 is a top view schematic diagram of a differential pair structure 400 of an embodiment of the disclosure. Different from the differential pair structure 200, the differential pair structure 400 includes an electrode ED_C instead of the electrode ED3 and the electrode ED4. In detail, as shown in FIG. 4, the electrode ED_C is arranged in the well WL_1 and surrounds the transistor M1, the transistor M2, the electrode ED1, and the electrode ED2. Similar to the the electrode ED3 and the ED4 of the differential pair structure 200, the electrode ED_C may also be configured to receive the bias VBB. Additionally, in FIG. 4, the electrode ED_C is rectangular. However, those skilled in the art may change the shape of the electrode ED_C according to requirements without certain limitations.

It is worth mentioning that in the differential pair structures 200, 300 and 400 of FIG. 2A, FIG. 2B and FIG. 3 to FIG. 4 above, the sub-transistor M1_1 and the sub-transistor M1_2 are connected in parallel, and the sub-transistor M2_1 and the sub-transistor M2_2 are connected in parallel.

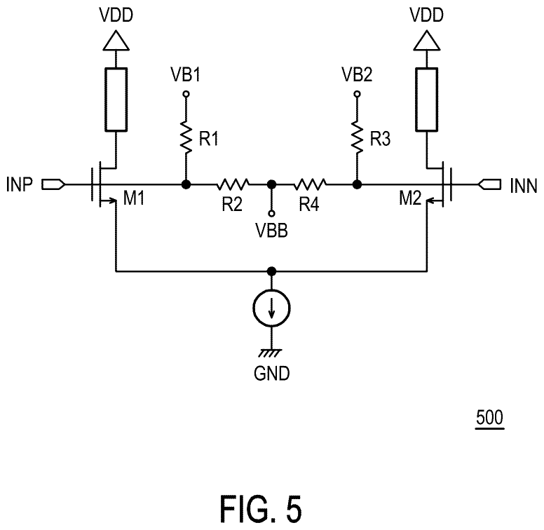

Referring to FIG. 5, FIG. 5 is a schematic diagram of an equivalent circuit 500 of differential pair structures 200, 300, 400 of an embodiment of the disclosure. As shown in FIG. 2A, for the differential pair structure 200, in the well WL_1, a resistor R1 and a resistor R2 connected in series (equal to a resistor with a resistance value of V_R1+V_R2, where V_R1 and V_R2 are the resistance values of the resistor R1 and the resistor R2 respectively) are formed between the electrode ED3 and the electrode ED1. A resistor R3 and a resistor R4 connected in series (equal to a resistor with a resistance value of V_R3+V_R4, where V_R3 and V_R4 are the resistance values of the resistor R3 and the resistor R4 respectively) are formed between the electrode ED4 and the electrode ED2. Similarly, for the differential pair structure 300, in the well WL_1, a resistor R1 and a resistor R2 connected in series (equal to a resistor with a resistance value of V_R1+V_R2, where V_R1 and V_R2 are the resistance values of the resistor R1 and the resistor R2 respectively) are formed between the electrode ED5 and the electrode ED1. A resistor R3 and a resistor R4 connected in series (equal to a resistor with a resistance value of V_R3+V_R4, where V_R3 and V_R4 are the resistance values of the resistor R3 and the resistor R4 respectively) are formed between the electrode ED6 and the electrode ED2. Similarly, for the differential pair structure 400, in the well WL_1, a resistor R1 and a resistor R2 connected in series (i.e., a resistor having a resistance value of V_R1+V_R2) are formed between the electrode ED_C and the electrode ED1. A resistor R3 and a resistor R4 connected in series (i.e., a resistor having a resistance value of V_R3+V_R4) are formed between the electrode ED_C and the electrode ED2. In addition, as mentioned in the previous paragraph, in some implementations of this embodiment, the sub-transistor M1_1 and the sub-transistor M1_2 are connected in parallel, and the sub-transistor M2_1 and the sub-transistor M2_2 are connected in parallel. The transistor M1 having sub-transistors M1_1 and M1_2 connected in parallel may be regarded as a transistor with two control terminals. The control terminals of the transistor M1 may be further coupled to a node to serve as a single input terminal of the transistor M1. In the same way, the transistor M2 may also be regarded as a transistor with a single input terminal. Therefore, the differential pair structure 200, 300 or 400 may be simplified to the equivalent circuit 500 shown in FIG. 5.

In the equivalent circuit 500, the input terminal INP of the transistor M1 and the input terminal INN of the transistor M2 serve as terminals for the differential pair structure 200, 300 or 400 to receive differential signals. The transistor M1 and the transistor M2 are connected in parallel between the power supply voltage VDD and the ground terminal GND. The base of the transistor M1 is coupled to the voltage VB1 via the resistor R1, and the base of the transistor M2 is coupled to the voltage VB2 via the resistor R2. The base of the transistor M1 and the base of the transistor M2 are coupled to the voltage VBB via the resistor R3 and the resistor R4 respectively.

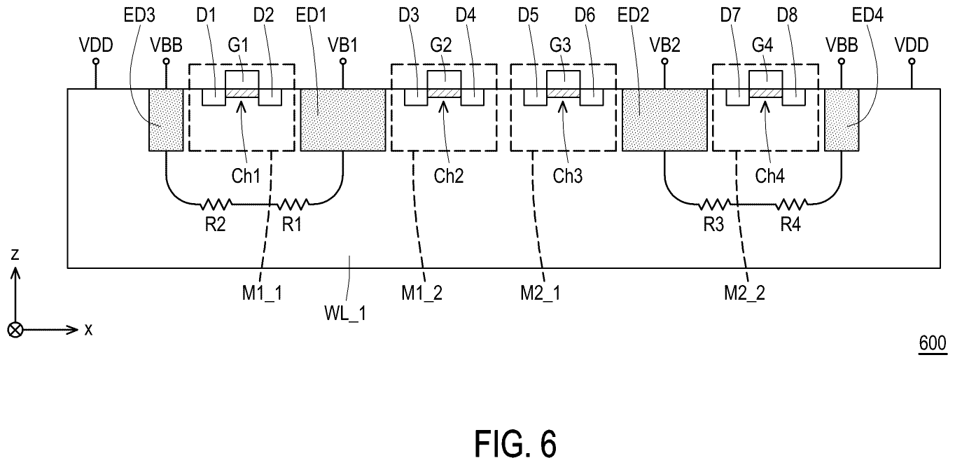

Referring to FIG. 2A and FIG. 6 together, FIG. 6 is a schematic diagram of the lateral structure of a differential pair structure 600 of an embodiment of the disclosure. Different from the differential pair structure 200 in FIG. 2A, the heavily doped regions D1 to D8 of the differential pair structure 600 are all P-type heavily doped regions, the well WL_1 of the differential pair structure 600 is an N-type well, and the differential pair structure 600 receives the power supply voltage VDD through the well WL_1. In this way, the sub-transistors M1_1, M1_2, M2_1, and M2_2 of the differential pair structure 600 are P-type transistors. The other arrangements of the differential pair structure 600 are the same as those of the differential pair structure 200 and are not repeated herein.

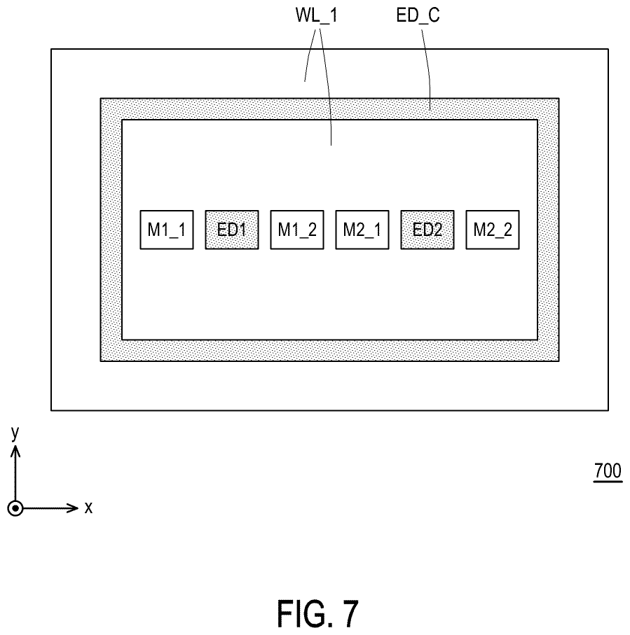

Referring to FIG. 4 and FIG. 7 together, FIG. 7 is a top view schematic diagram of a differential pair structure 700 of an embodiment of the disclosure. Different from the differential pair structure 400 in FIG. 4, the conductive polarities of the sub-transistors M1_1, M1_2, M2_1, M2_2, and the well WL_1 of the differential pair structure 700 are respectively opposite to the conductive polarities of the sub-transistors M1_1, M1_2, M2_1, M2_2, and the well WL_1 of the differential pair structure 400. For example, the sub-transistor M1_1 of the differential pair structure 700 is a P-type transistor, and the sub-transistor M1_1 of the differential pair structure 400 is an N-type transistor. For another example, the well WL_1 of the differential pair structure 700 is an N-type well, and the well WL_1 of the differential pair structure 400 is a P-type well.

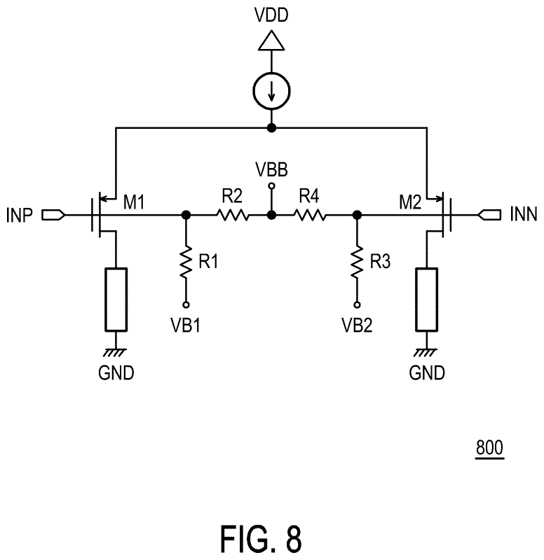

Referring to FIG. 8, FIG. 8 is a schematic diagram of an equivalent circuit 800 of differential pair structures 600, 700 of an embodiment of the disclosure. Corresponding to the difference in conductive polarity between the differential pair structure 200 and the differential pair structure 600 (or the differential pair structure 400 and the differential pair structure 700), the difference between the equivalent circuit 800 and the equivalent circuit 500 lies in the reversal of the terminals of the transistor coupled to the power supply voltage VDD and the ground terminal GND. In the equivalent circuit 500, the transistor M1 and the transistor M2 are coupled to the ground terminal GND via their respective sources, and coupled to the power supply voltage VDD via their respective drains. On the contrary, in the equivalent circuit 800, the transistor M1 and the transistor M2 are coupled to the ground terminal GND via their respective drains, and coupled to the power supply voltage VDD via their respective sources. The other arrangements of the equivalent circuit 800 are the same as those of the equivalent circuit 500 and are not repeated herein.

To sum up, in the differential pair structure of the embodiment of the disclosure, the transistor pair and the electrode are arranged in the same well, and the electrode is used as the symmetry point of the transistor pair. As a result, a differential pair structure with smaller transistor spacing is produced, which may effectively reduce space costs and parasitic effects.

What is claimed is:

1. A differential pair structure, comprising:
a first well;
a first electrode and a second electrode, arranged in the first well;
a first transistor, having a plurality of sub-transistors arranged in the first well symmetrically with respect to the first electrode along a first direction; and
a second transistor, having a plurality of sub-transistors arranged in the first well symmetrically with respect to the second electrode along the first direction,
wherein the first electrode and the second electrode respectively receive a first bias and a second bias.

2. The differential pair structure according to claim 1, wherein the first bias is different from the second bias.

3. The differential pair structure according to claim 1, wherein the sub-transistors of the first transistor comprises:
a first sub-transistor, arranged in the first well and adjacent to a first side of the first electrode; and
a second sub-transistor, arranged in the first well and adjacent to a second side of the first electrode, wherein the first side is opposite to the second side.

4. The differential pair structure according to claim 3, wherein the first sub-transistor and the second sub-transistor are connected in parallel.

5. The differential pair structure according to claim 3, wherein the sub-transistors of the second transistor comprise:
a third sub-transistor, arranged in the first well and adjacent to a first side of the second electrode; and
a fourth sub-transistor, arranged in the first well and adjacent to a second side of the second electrode, wherein the first side is opposite to the second side.

6. The differential pair structure according to claim 5, wherein each of the first sub-transistor to the fourth sub-transistor comprises:
a first heavily doped region;
a second heavily doped region, arranged in the first well with the first heavily doped region along the first direction, wherein the first heavily doped region and the second heavily doped region form a channel region; and
a gate structure, covering the channel region.

7. The differential pair structure according to claim 6, wherein the first heavily doped region and the second heavily doped region are both N-type heavily doped regions or both P-type heavily doped regions.

8. The differential pair structure according to claim 1, further comprising:
a third electrode, arranged in the first well and surrounding the first transistor, the second transistor, the first electrode, and the second electrode.

9. The differential pair structure according to claim 8, wherein, in the first well, a first resistor is formed between the third electrode and the first electrode;
in the first well, a second resistor is formed between the third electrode and the second electrode.

10. The differential pair structure according to claim 8, wherein the third electrode receives a third bias.

11. The differential pair structure according to claim 10, wherein a voltage value of the third bias is equal to an average value of voltage values of the first bias and the second bias.

12. The differential pair structure according to claim 1, further comprising:
a third electrode; and
a fourth electrode, wherein the third electrode and the fourth electrode are respectively arranged on two sides of the first well in a vertical direction,
wherein the third electrode and the fourth electrode receive a same third bias.

13. The differential pair structure according to claim 1, further comprising:
a third electrode; and
a fourth electrode, wherein the third electrode and the fourth electrode are respectively arranged on two sides of the first well in a horizontal direction,
wherein the third electrode and the fourth electrode receive a same third bias.

14. The differential pair structure according to claim 1, further comprising:
a second well;
wherein the first well is arranged in the second well.

15. The differential pair structure according to claim 14, wherein a conductive polarity of the first well is opposite to a conductive polarity of the second well.
